(19) United States
(12) Patent Application Publication
(10) Pub. No.: US 2023/0408648 A1
(43) Pub. Date: Dec. 21, 2023

(54) COMPUTER-IMPLEMENTED METHOD AND SYSTEM FOR DETERMINING AN ARRANGEMENT OF COMPONENTS OF AN OVER-THE-AIR TEST CHAMBER

(71) Applicant: dSPACE GmbH, Rathenaustr. 26 (DE)

(72) Inventors: Dirk BERNECK, Paderborn (DE); Andreas HIMMLER, Paderborn (DE); Fabian HAPP, Paderborn (DE)

(73) Assignee: dSPACE GmbH, Paderborn (DE)

(21) Appl. No.: 18/211,836

(22) Filed: Jun. 20, 2023

(30) Foreign Application Priority Data
Jun. 21, 2022 (DE) 10 2022 115 432.7
Jul. 19, 2022 (DE) 10 2022 118 058.1

(51) Int. Cl. G01S 7/40; G01R 29/08

(52) U.S. Cl. CPC G01S 7/4086; G01R 29/0892

(57) ABSTRACT

A computer-implemented method and system for determining an arrangement of components of an over-the-air test chamber, comprising a determination of position data of an optimized arrangement of the components in the over-the-air test chamber in relation to each other and/or a grouping of position data of an optimized arrangement in the over-the-air test chamber, and an output of a second data set comprising the position of the optimized arrangement of the DUT, in particular the radar sensor, the reflector and the target simulator or the transmitting/receiving device of the target simulator in the over-the-air test chamber, and/or the grouping of the optimized arrangement in the over-the-air test chamber.

This nonprovisional application claims priority under 35 U.S.C. § 119(a) to German Patent Application No. 10 2022 115 432.7, which was filed in Germany on Jun. 21, 2022, and to German Patent Application No. 10 2022 118 058.1, which was filed in Germany on Jul. 19, 2022, and which are both herein incorporated by reference.

### BACKGROUND OF THE INVENTION

### Field of the Invention

The present invention relates to a computer-implemented method for determining an arrangement of components of an over-the-air test chamber, in particular a CATR chamber. The invention further relates to a system for determining an arrangement of components of an over-the-air test chamber, in particular a CATR chamber. Furthermore, the invention relates to a computer-implemented method for testing components in an over-the-air test chamber, in particular a CATR chamber. The invention also relates to an over-the-air test chamber, in particular a CATR chamber.

### Description of the Background Art

End-of-line CATR test systems for radar sensors perform automated testing and calibration of mass-produced radar sensors for use in vehicles.

An end-of-line test bench for mass-produced automotive radar sensors is required to test the functionality of fully assembled modules and to calibrate them automatically within a particularly compact anechoic chamber by means of radar target simulation. The measurement of operating parameters of the radar sensors (radar under test) and their calibration is carried out in a defined test sequence in which the radar sensor is rotated around its radiation center in horizontal and vertical directions by means of high-precision drives.

The Device Under Test (DUT) or radar under test is placed manually or by a robot in the DUT holder of the test system, which is protected by a safety light curtain. This is where the sensor is fixed, the sensor type is checked by means of a barcode and the sensor position is checked. Subsequently, the electrical connections are mechanically contacted, the sensor is moved into the anechoic chamber and the anechoic chamber is closed by means of an anechoic bulkhead.

In the anechoic chamber there is a robot that performs the relative motion around its radiation center, a reflector with a parabolic surface contour and the transmitting/receiving antenna of a target simulator in the focal point of the reflector.

The reflector bundles the radar waves emitted by the radar sensor and deflects them to the receiving antenna of the target simulator. The radar target simulator imprints targets on the radar waves and returns the manipulated waves as echoes via the reflector to the DUT. The resulting plane wavefront is independent of the sensor-specific far-field distance, which is why CATR methodology makes it possible to use a compact design instead of a very large test chamber (often over 10 m in length).

During the testing and calibration of the radar sensor, it is rotated horizontally (azimuth) and vertically (elevation) around its radiation center, whereby the antenna pattern with its power levels is recorded at the respective angle. The transmitting and receiving antennas of the radar sensor are characterized and measured. Functional results such as correctly recognized targets and their properties can be output as test results, as well as the acquisition characteristics of the respective DUT.

U.S. Pat. No. 10,536,228 discloses a test system for testing a DUT on the floor of a test chamber, comprising a measuring antenna mounted on the floor or on a side wall of the test chamber, wherein the measuring antenna is designed to send outgoing test signals to the DUT and to receive incoming test signals sent by the DUT, and a reflector mounted on a ceiling of the test chamber, wherein the reflector is designed to collimate the test signals emitted by the measuring antenna in the direction of the DUT, so that a homogeneous radiation of the DUT is achieved, and that it focuses the test signals emitted by the DUT in the direction of the measuring antenna, wherein high-frequency waves run parallel in relation to each other between the DUT and the reflector, and the side walls of the test chamber are not covered by the test signals, the reflector focuses the radio frequency waves emitted by the DUT onto the measuring antenna, and wherein a signal path of the outgoing test signals and the incoming test signals between the DUT and the reflector runs in a vertical direction.

As a result, there is a need to improve existing methods and systems for testing components in an over-the-air test chamber to enable the determination of an optimal CATR arrangement with regard to the development parameters of footprint, height and DUT movement.

### SUMMARY OF THE INVENTION

It is therefore an object of the present invention to provide a computer-implemented method and system for determining an arrangement of components of an over-the-air test chamber, in particular a CATR chamber, which enable an optimal CATR arrangement with respect to the development parameters of footprint, height and DUT movement.

According to the invention, the object is achieved by a computer-implemented method for determining an arrangement of components of an over-the-air test chamber, in particular a CATR chamber.

The method comprises the provision of a first data set comprising a position of an initial arrangement of a DUT, in particular a radar sensor, a reflector and a target simulator or a transmitting/receiving device of the target simulator in the over-the-air test chamber, wherein the target simulator emits test signals that are that are reflected, in particular collimated, by the reflector to the DUT and receives incoming test signals from the DUT. The reflector is designed as a parabolic mirror.

The initial arrangement corresponds to a previously or conventionally used arrangement of the components in the over-the-air test chamber, in particular the CATR chamber.

Furthermore, the method includes a determination of position data of an optimized arrangement of the components in the over-the-air test chamber in relation to each other and/or position data of an optimized arrangement of a grouping of the components in the over-the-air test chamber.

The method further includes the output of a second data set comprising the position of the optimized arrangement of the DUT, in particular the radar sensor, the reflector and the target simulator or the transmitting/receiving device of the target simulator in the over-the-air test chamber, and/or the optimized arrangement of the grouping of the components in the over-the-air test chamber.

The invention further relates to a system for determining an arrangement of components of an over-the-air test chamber, in particular a CATR chamber.

The system comprises a data memory which is configured to provide a first data set comprising a position of an initial arrangement of a DUT, in particular a radar sensor, a reflector and a target simulator or a transmitting/receiving device of the target simulator in the over-the-air test chamber, wherein the target simulator is configured to send test signals that are reflected, in particular collimated, by the reflector to the DUT and to receive incoming test signals from the DUT.

Furthermore, the system includes a calculation unit which is configured to determine position data of an optimized arrangement of the components in the over-the-air test chamber in relation to each other and/or position data of an optimized arrangement of a grouping of the components in the over-the-air test chamber.

The system also includes an output unit which is configured to output a second data set comprising the position of the optimized arrangement of the DUT, in particular the radar sensor, the reflector and the target simulator or the transmitting/receiving device of the target simulator in the over-the-air test chamber, and/or the optimized arrangement of the grouping of the components in the over-the-air test chamber.

For example, the calculation unit and the output unit may be integrated into a unit or device.

The invention further relates to a computer-implemented method for testing components in an over-the-air test chamber, in particular a CATR chamber.

The method comprises a test of the components in the over-the-air test chamber using the second data set, comprising the position of the optimized arrangement of the DUT, in particular the radar sensor, the reflector and the target simulator or the transmitting/receiving device of the target simulator in the over-the-air test chamber and/or comprising the position of the grouping of the optimized arrangement in the over-the-air test chamber with the method according to the invention for determining an arrangement of components of an over-the-air test chamber, in particular a CATR chamber.

The invention also relates to an over-the-air test chamber, in particular a CATR chamber for testing components.

The over-the-air test chamber comprises the components arranged therein, in particular a radar sensor, a reflector and a target simulator, wherein the over-the-air test chamber is configured to test the components using the second data set of the optimized arrangement of the DUT, in particular the radar sensor, the reflector and the target simulator or the transmitting/receiving device of the target simulator in the over-the-air test chamber and/or comprising the position of the grouping of the optimized arrangement in the over-the-air test chamber with the method according to the invention for determining an arrangement of components of an over-the-air test chamber, in particular a CATR chamber.

The invention further relates to a computer program containing program code to carry out at least one of the methods according to the invention when the computer program is executed on a computer.

In addition, the invention relates to a computer-readable medium containing program code of a computer program to carry out at least one of the methods according to the invention when the computer program is executed on a computer.

An idea of the present invention is to allow for more degrees of freedom in the design of a CATR chamber by positioning the basic elements of the CATR arrangement differently in relation to each other, as well as by being able to be optimally arranged in the chamber as a whole group by rotation.

The invention further makes it possible to find the optimal CATR arrangement with regard to the development parameters of footprint, height and radar under test movement. In this case, the arrangement of the determining components in relation to each other and in the room is defined by optimizing the CATR arrangement.

The method can include that the determination of position data of the optimized arrangement of the components in the over-the-air test chamber in relation to each other involves determining the position of an optimized arrangement of the reflector, which has a different orientation in a projection plane of the DUT, in particular the radar sensor, as compared to the initial arrangement.

The realignment of the reflector thus advantageously enables a more compact arrangement of the components in the over-the-air test chamber.

The method can also include that determining the position of the optimized arrangement of the reflector involves rotating the reflector by a specified angle, especially in an angular range of 1-20°, around a central axis of the reflector.

Thus, an optimized beam angle of the reflector in the over-the-air test chamber can be obtained in an advantageous manner.

The method can include that the determination of position data of the optimized arrangement of the components in the over-the-air test chamber in relation to each other involves determining a position of an optimized arrangement of a transmitting/receiving antenna of a radar sensor, which arrangement lies in a quiet zone of the reflector. In the quiet zone, there are approximate far-field conditions. This enables an optimal arrangement of the components in relation to each other.

The method can include that determining the position of the optimized arrangement of the transmitting/receiving antenna of the radar sensor involves moving the transmitting/receiving antenna of the radar sensor to the projection plane of the DUT, in particular the radar sensor.

Moving the transmitting/receiving antenna of the radar sensor to the projection plane of the DUT advantageously enables it to be arranged in an optimal reception area.

The method can include that the determination of position data of the optimized arrangement of the components in the over-the-air test chamber in relation to each other involves determining an orientation of the transmitting/receiving antenna of a radar sensor to the reflector in such a way that the test signals of the DUT, in particular the radar sensor, strike the reflector in the middle. As a result, an optimal positioning of the reflector relative to the other components can be achieved in an advantageous manner.

The method can include that determining the orientation of the transmitting/receiving antenna of the radar sensor to the reflector involves rotating the transmitting/receiving antenna of the radar sensor around a central axis of the radar sensor.

The realignment of the transmitting/receiving antenna of the radar sensor thus advantageously enables a more compact arrangement of the components in the over-the-air test chamber.

The method can include that the determination of position data of the grouping of the optimized arrangement in the over-the-air test chamber involves rotating the grouping of the optimized arrangement in the over-the-air test chamber by a specified angle of rotation around a specified axis of rotation.

By rotating the grouping of the optimized arrangement in the over-the-air test chamber, a different, more compact arrangement of the grouping of the optimized arrangement in the over-the-air test chamber can be advantageously achieved.

The method can include that rotating the grouping of the optimized arrangement in the over-the-air test chamber by a predetermined angle of rotation around a predetermined axis of rotation includes rotating the grouping of the optimized arrangement in the over-the-air test chamber by a longitudinal and/or transverse axis of the grouping of the optimized arrangement in the over-the-air test chamber.

Thus, maximum flexibility can be achieved in an advantageous manner with regard to the positioning of the grouping of the optimized arrangement in the over-the-air test chamber.

The method can involve the over-the-air test chamber comprising or being actively connected with a robot, which robot is configured to rotate the radar sensor at a predetermined angle around a projection axis of the radar sensor during a test process.

Thus, in an advantageous manner, the radar sensor can be tested in different orientations in the over-the-air test chamber. Furthermore, a horizontal and a vertical radiation and/or reception characteristic of the radar sensor can be determined in an advantageous manner.

The features of the method described herein are also applicable to other virtual environments, such as testing other types of vehicles in different environments.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1A to 1C show flowcharts of a computer-implemented method for determining an arrangement of components of an over-the-air test chamber, in particular a CATR chamber, according to a preferred embodiment of the invention;

FIG. 2 is a diagram of a system for determining an arrangement of components of an over-the-air test chamber, in particular a CATR chamber, according to the preferred embodiment of the invention; and

FIG. 3 is a diagram of an over-the-air test chamber, in particular a CATR chamber for testing components according to the preferred embodiment of the invention.

### DETAILED DESCRIPTION

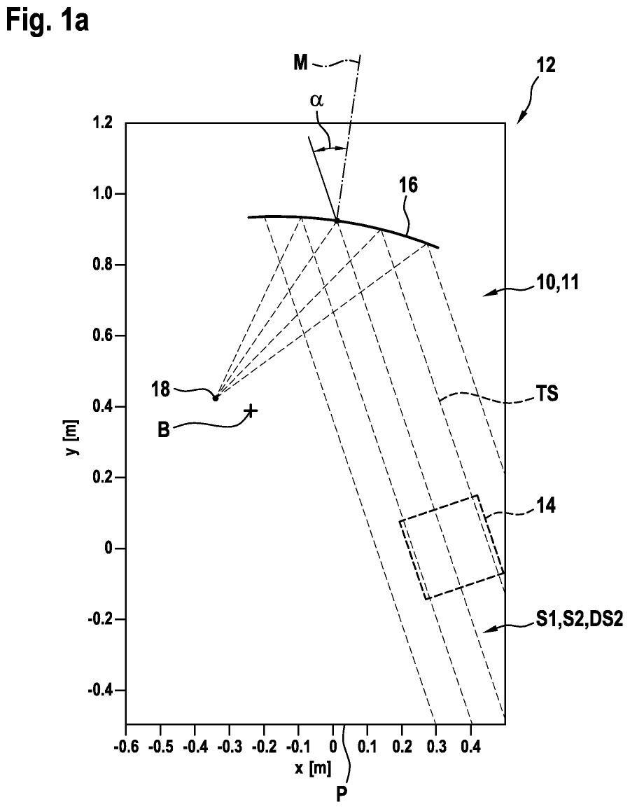

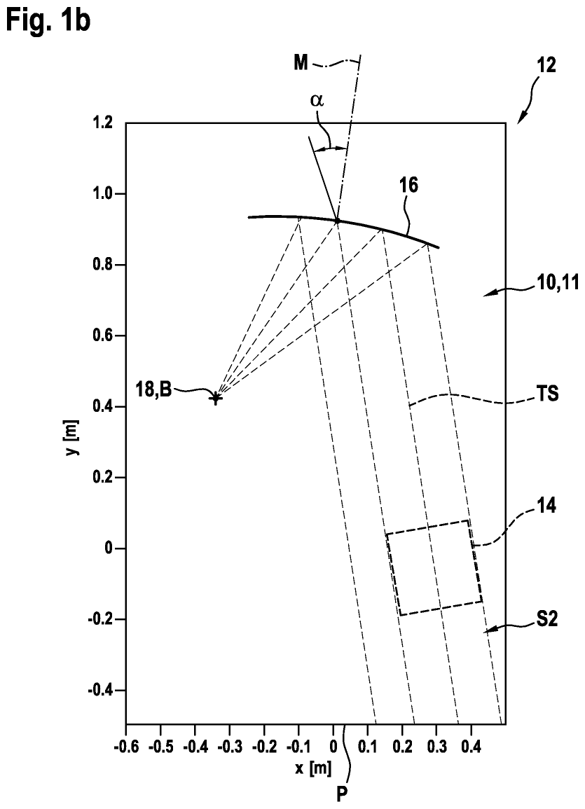

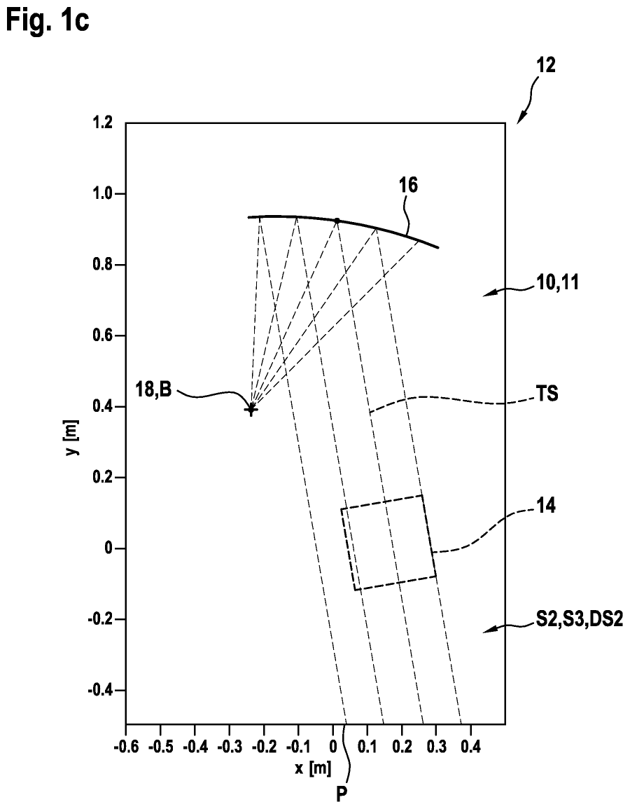

FIG. 1a shows a flowchart of a computer-implemented method for determining an arrangement 10 of components of an over-the-air test chamber 12, in particular a CATR chamber, according to a preferred embodiment of the invention.

The over-the-air test chamber 12 has an opening 26, in particular an anechoic bulkhead.

The method comprises the provision 51 of a first data set DS1 comprising a position of an initial arrangement of a DUT 14, in particular a radar sensor, a reflector 16 and a target simulator 18 or a transmitting/receiving device of the target simulator 18 in the over-the-air test chamber 12, wherein the target simulator 18 emits that are reflected, in particular collimated, test signals TS by the reflector 16 to the DUT 14 and receives incoming test signals TS from the DUT 14.

The DUT 14 is arranged in a quiet zone 30. Thus, interference-free measurements can be made possible.

Furthermore, the method includes a determination S2 of position data of an optimized arrangement 10 of the components in the over-the-air test chamber 12 in relation to each other and/or position data of an optimized arrangement 10 of a grouping 11 of the components in the over-the-air test chamber 12.

The method further comprises an output S3 of a second data set DS2 comprising the position of the optimized arrangement of the DUT 14, in particular the radar sensor, the reflector 16 and the target simulator 18 or the transmitting/receiving device of the target simulator 18 in the over-the-air test chamber 12, and/or the optimized arrangement 10 of the grouping 11 of the components in the over-the-air test chamber 12.

The determination S2 of position data of the optimized arrangement 10 of the components in the over-the-air test chamber 12 in relation to each other includes a determination of the position of an optimized arrangement of the reflector 16, which has a different orientation in a projection plane P of the DUT 14, in particular the radar sensor, as compared to the initial arrangement.

Further, determining the position of the optimized arrangement of the reflector 16 involves rotating the reflector 16 by a specified angle, in particular in an angular range of 1-20°, around a central axis M of the reflector 16.

FIG. 1b shows a flowchart of a computer-implemented method for determining an arrangement 10 of components of an over-the-air test chamber 12, in particular a CATR chamber, according to the preferred embodiment of the invention.

The determination S2 of position data of the optimized arrangement 10 of the components in the over-the-air test chamber 12 in relation to each other further includes a determination of a position of an optimized arrangement of a transmitting/receiving antenna 14a of a radar sensor, which arrangement lies in a quiet zone 30 of the reflector 16.

In addition, determining the position of the optimized arrangement of the transmitting/receiving antenna 14a of the radar sensor involves moving the transmitting/receiving antenna 14a of the radar sensor to the projection plane P of the DUT 14, in particular the radar sensor.

Furthermore, the target simulator 18 or a transmitting/receiving antenna of the target simulator 18 is moved to a focal point B of the previously rotated reflector 16.

FIG. 1c shows a flowchart of a computer-implemented method for determining an arrangement 10 of components of an over-the-air test chamber 12, in particular a CATR chamber, according to the preferred embodiment of the invention.

The determination S2 of position data of the optimized arrangement 10 of the components in the over-the-air test chamber 12 in relation to each other further includes determining an orientation of the transmitting/receiving antenna 14a of a radar sensor to the reflector 16 in such a way that the test signals TS of the DUT 14, in particular the radar sensor, strike the reflector 16 in the middle.

In addition, determining the orientation of the transmitting/receiving antenna 14a of the radar sensor to the reflector 16 involves rotating the transmitting/receiving antenna 14a of the radar sensor around a central axis of the radar sensor.

The determination S2 of position data of the optimized arrangement in the over-the-air test chamber 12 further includes, according to a method described in FIG. 1c, a rotation of the grouping 11 of the optimized arrangement in the over-the-air test chamber 12 by a specified angle of rotation around a specified axis of rotation.

The above-mentioned alternative embodiment can also be combined or integrated, for example, with the one shown in FIGS. 1a-c.

The rotation of the grouping 11 of the optimized arrangement in the over-the-air test chamber 12 by a specified angle of rotation around a specified axis of rotation further includes rotating the grouping 11 of the optimized arrangement in the over-the-air test chamber 12 by a longitudinal and/or transverse axis of the grouping 11 of the optimized arrangement in the over-the-air test chamber 12.

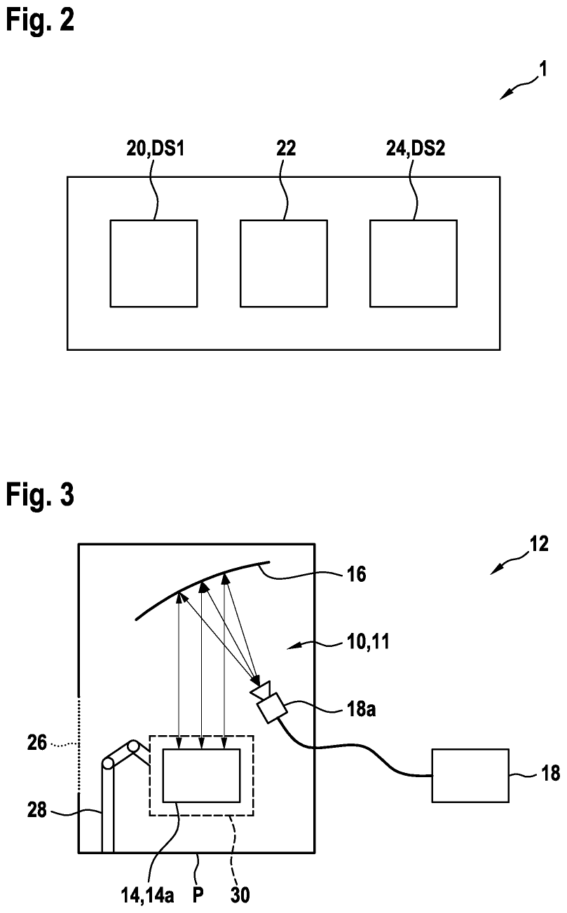

FIG. 2 shows a diagram of a system 1 for determining an arrangement 10 of components of an over-the-air test chamber 12, in particular a CATR chamber, according to the preferred embodiment of the invention.

The system 1 comprises a data memory 20, which is configured to provide a first data set DS1 comprising a position of an initial arrangement of a DUT 14, in particular a radar sensor, a reflector 16 and a target simulator 18 or a transmitting/receiving device of the target simulator 18 in the over-the-air test chamber 12, wherein the target simulator 18 is configured to emit that are reflected, in particular collimated, test signals TS by the reflector 16 to the DUT 14 and to receive incoming test signals TS from the DUT 14.

Furthermore, the system 1 comprises a calculation unit 22 which is configured to determine position data of an optimized arrangement 10 of the components in the over-the-air test chamber 12 in relation to each other and/or position data of an optimized arrangement 10 of a grouping 11 of the components in the over-the-air test chamber 12.

The system 1 also comprises an output unit 24 which is configured to output a second data set DS2 comprising the position of the optimized arrangement of the DUT 14, in particular the radar sensor, the reflector 16 and the target simulator 18 or the transmitting/receiving device of the target simulator 18 in the over-the-air test chamber 12, and/or the optimized arrangement 10 of the grouping 11 of the components in the over-the-air test chamber 12.

FIG. 3 shows a diagram of an over-the-air test chamber 12, in particular a CATR chamber for testing components, according to the preferred embodiment of the invention.

The over-the-air test chamber 12, in particular the CATR chamber for testing components, comprises components arranged in the over-the-air test chamber 12, in particular a radar sensor, a reflector 16 and a target simulator 18, wherein the over-the-air test chamber 12 is configured to test the components using the second data set DS2 of the optimized arrangement of the DUT 14, in particular the radar sensor, the reflector 16 and the target simulator 18 or the transmitting/receiving device 18a of the target simulator 18 in the over-the-air test chamber 12 and/or including the position of the grouping 11 of the optimized arrangement in the over-the-air test chamber 12 using a method according to the invention.

According to an example illustrated in FIG. 3, the target simulator 18 is arranged outside the over-the-air test chamber 12. For this purpose, the transmitting/receiving device 18a, in particular a transmitting/receiving antenna, is provided in the over-the-air test chamber 12, which is connected to the target simulator 18 arranged outside the over-the-air test chamber 12 via a cable connection or wirelessly. Alternatively, the target simulator 18 may be arranged, for example, in the over-the-air test chamber 12.

The over-the-air test chamber 12 further comprises or is in active connection with a robot 28, which robot 28 is configured to rotate the radar sensor by a predetermined angle α around a projection axis of the radar sensor during a test process.

Although specific embodiments have been illustrated and described herein, it is understandable to those skilled in the art that a variety of alternative and/or equivalent implementations exist. It should be noted that the exemplary embodiment or exemplary embodiments are only examples and are not intended to limit the scope, applicability or configuration in any way.

Rather, the above-mentioned summary and detailed description provides the skilled person with convenient instructions for the implementation of at least one exemplary embodiment, it being understandable that various changes can be made in the range of functions and arrangement of the elements without deviating from the scope of the attached claims and their legal equivalents.

Generally, this application is intended to cover changes or adaptations or variations of the embodiments presented herein. For example, the sequence of the method steps can be changed. The method may also be carried out sequentially or in parallel, at least in sections.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for determining an arrangement of components of an over-the-air test chamber, in particular a CATR chamber, the method comprising:
providing a first data set comprising a position of an initial arrangement of a DUT in the over-the-air test chamber, wherein the target simulator emits test signals that are reflected or collimated by the reflector to the DUT and receives test signals from the DUT;
determining position data of an optimized arrangement of the components in the over-the-air test chamber in relation to each other and/or position data of an optimized arrangement of a grouping of the components in the over-the-air test chamber; and
outputting a second data set comprising the position of the optimized arrangement of the DUT in the over-the-air test chamber and/or the optimized arrangement of the grouping of the components in the over-the-air test chamber.

2. The computer-implemented method according to claim 1, wherein the determination of position data of the optimized arrangement of the components in the over-the-air test chamber in relation to each other involves determining the position of an optimized arrangement of the reflector, which has a different orientation in a projection plane of the DUT as compared to the initial arrangement.

3. The computer-implemented method according to claim 2, wherein determining the position of the optimized arrangement of the reflector involves a rotation of the reflector by a specified angle, in particular in an angular range of 1-20°, around a central axis of the reflector.

4. The computer-implemented method according to claim 1, wherein the determination of position data of the optimized arrangement of the components in the over-the-air test chamber in relation to each other includes determining a position of an optimized arrangement of a transmitting/receiving antenna of a radar sensor, which arrangement lies in a quiet zone of the reflector.

5. The computer-implemented method according to claim 4, wherein the determination of the position of the optimized arrangement of the transmitting/receiving antenna of the radar sensor involves moving the transmitting/receiving antenna of the radar sensor to the projection plane of the DUT, in particular the radar sensor.

6. The computer-implemented method according to claim 1, wherein the determination of position data of the optimized arrangement of the components in the over-the-air test chamber in relation to each other includes determining an orientation of the transmitting/receiving antenna of a radar sensor to the reflector in such a way that the test signals of the DUT strike the reflector in the middle.

7. The computer-implemented method according to claim 6, wherein a determination of the orientation of the transmitting/receiving antenna of the radar sensor to the reflector involves rotating the transmitting/receiving antenna of the radar sensor around a central axis of the radar sensor.

8. The computer-implemented method according to claim 1, wherein the determination of position data of the grouping (of the optimized arrangement in the over-the-air test chamber involves rotating the grouping of the optimized arrangement in the over-the-air test chamber by a specified angle of rotation around a specified axis of rotation.

9. The computer-implemented method according to claim 8, wherein the rotation of the grouping of the optimized arrangement in the over-the-air test chamber by a specified angle of rotation around a specified axis of rotation includes a rotation of the grouping of the optimized arrangement in the over-the-air test chamber by a longitudinal and/or transverse axis of the grouping of the optimized arrangement in the over-the-air test chamber.

10. A system for determining an arrangement of components of an over-the-air test chamber, in particular a CATR chamber, the system comprising:
a data memory configured to provide a first data set comprising a position of an initial arrangement of a DUT, which is a radar sensor, a reflector, a target simulator or a transmitting/receiving device of the target simulator in the over-the-air test chamber, wherein the target simulator is configured to emit test signals that are reflected or collimated by the reflector to the DUT and to receive incoming test signals from the DUT;
a calculation unit, which is configured to determine position data of an optimized arrangement of the components in the over-the-air test chamber in relation to each other and/or position data of an optimized arrangement of a grouping of the components in the over-the-air test chamber; and
an output unit, which is configured to output a second data set comprising the position of the optimized arrangement of the DUT, in particular the radar sensor, the reflector and the target simulator or the transmitting/receiving device of the target simulator in the over-the-air test chamber, and/or the optimized arrangement of the grouping of the components in the over-the-air test chamber.

11. A computer-implemented method for testing components in an over-the-air test chamber, in particular a CATR chamber, the method comprising:
testing the components in the over-the-air test chamber using the second data set comprising the position of the optimized arrangement of the DUT, which is a radar sensor, a reflector, a target simulator, or a transmitting/receiving device of the target simulator in relation to each other in the over-the-air test chamber; and/or
determining the position of the grouping of the optimized arrangement in the over-the-air test chamber with the method according to claim 1.

12. An over-the-air test chamber, in particular CATR chamber for testing components, the test chamber comprising:
components located in the over-the-air test chamber, in particular a radar sensor, a reflector and a target simulator or a transmitting/receiving device of the target simulator, wherein the over-the-air test chamber is configured to test the components using the second data set of the optimized arrangement of the DUT, in particular the radar sensor, the reflector and the target simulator or the transmitting/receiving device of the target simulator in relation to each other in the over-the-air test chamber, and/or the grouping of the optimized arrangement in the over-the-air test chamber using the method according to claim 1.

13. The over-the-air test chamber according to claim 12, wherein the over-the-air test chamber comprises or is in active connection with a robot, which robot is configured to rotate the radar sensor by a specified angle around a projection axis of the radar sensor during a test process.

14. A computer program containing program code, for carrying out the method according to claim 1 when the computer program is executed on a computer.

15. A computer-readable medium containing program code of a computer program, for carrying out the method according to claim 1, when the computer program is executed on a computer.

16. The method according to claim 1, wherein the DUT is a radar sensor, a reflector, a target simulator or a transmitting/receiving device of the target simulator.
